(19) United States
(12) Patent Application Publication
(10) Pub. No.: US 2026/0349944 A1
(43) Pub. Date: Nov. 5, 2026

(54) ELECTRONIC CONTROL APPARATUS

(71) Applicant: Mitsubishi Electric Mobility Corporation, Tokyo (JP)

(72) Inventors: Isao TOTTORI, Tokyo (JP); Kenichi FUJIE, Tokyo (JP)

(73) Assignee: Mitsubishi Electric Mobility Corporation, Tokyo (JP)

(21) Appl. No.: 19/131,072

(22) PCT Filed: Apr. 13, 2023
(86) PCT No.: PCT/JP2023/014965

§ 371 Date: May 19, 2025

(51) Int. Cl. G06F 13/36; H05K 5/00; H05K 9/00

(52) U.S. Cl. CPC G06F 13/36; H05K 5/0026; H05K 9/006; G06F 2213/40

(57) ABSTRACT

An electronic control apparatus has a connector mounted on a control board, a signal processing means mounted on the control board, and a signal wiring lead connecting the connector and the signal processing means; the signal wiring lead includes two or more individual signal wiring leads; the signal processing means performs signal allocation to the two or more individual signal wiring leads.

### TECHNICAL FIELD

The present disclosure relates to an electronic control apparatus.

### BACKGROUND ART

In recent years, a large number of electronic control apparatuses are mounted in an automobile. In addition, while electrification of automobiles such as a hybrid vehicle and an electric automobile is promoted, a large number of new automobile manufacturers are existing. Accordingly, for example, with regard to an electric-power conversion apparatus for driving an automobile motor, compatibility between diversity and universality among a large number of automobile manufacturers is required, and, moreover, shortening of apparatus-development period, cost reduction, and the like are required.

For example, a conventional connector apparatus with an electronic control switch, disclosed in Patent Document 1, is configured in such a way as to have two or more electric wiring leads that can be changed through electric switching action by a switching device, a connector having two or more terminals and capable of connecting one end of each of the electric wiring leads with an external apparatus, a control apparatus for controlling the switching device, and a memory device for providing switch-control data to the control apparatus and in such a way that at least one of the two or more terminals is utilized to rewrite the switch-control data to be stored in the memory device.

### Prior Art Reference

### [Patent Document]

[Patent Document 1] Japanese Patent Application Laid-Open No. H11-26095

### DISCLOSURE OF THE INVENTION

### Problems to be Solved by the Invention

The conventional apparatus disclosed in Patent Document 1 performs switching control of multi-channel circuit wiring leads by utilizing at least one of the two or more terminals in rewriting the switch-control data to be stored in the memory device, so that signal allocation of connector pins to signal wiring leads can be changed without changing the outer shape of the connector; however, in the case where the degree of flexibility in signal allocation of the connector pins to the signal wiring leads is raised or in the case where the number of the input/output signal pins of the connector and the number of the signal wiring leads are large, the number of the switching devices increases; thus, there have been problems that the outer-shape size of the connector is enlarged and that the manufacturing cost increases.

The present disclosure is to disclose a technology for solving the foregoing problems; the objective thereof is to provide an electronic control system that: realizes compatibility between diversity and universality.

### Means for Solving the Problems

An electronic control apparatus disclosed in the present disclosure is configured to control a control subject, and includes
a control board,
a connector mounted on the control board, and
a signal processing means that is mounted on the control board and is electrically connected with the connector by way of a signal wiring lead provided on the control board; the electronic control apparatus is characterized
in that an input/output signal bound for the connector is applied to the signal wiring lead and
in that the signal processing means performs signal allocation in which the input/output signal is allocated to the signal wiring

### Advantage of the Invention

The present disclosure makes it possible to obtain an electronic control apparatus that realizes compatibility between diversity and universality.

### BRIEF DESCRIPTION OF THE DRAWINGS

FIG. 1 is a block diagram representing the configuration of an electronic control apparatus according to Embodiment 1;

FIG. 2A is a block diagram representing the configuration of a first variant example in the electronic control apparatus according to Embodiment 1;

FIG. 2B is a block diagram representing the configuration of a second variant example in the electronic control apparatus according to Embodiment 1;

FIG. 2C is a block diagram representing the configuration of a third variant example in the electronic control apparatus according to Embodiment 1;

FIG. 3A is a circuit diagram representing an example of an exogenous-noise protection circuit in the electronic control apparatus according to Embodiment 1;

FIG. 3B is a circuit diagram representing another example of the exogenous-noise protection circuit in the electronic control apparatus according to Embodiment 1;

FIG. 4 is a flowchart representing an example of signal allocation processing by a signal processing means in the electronic control apparatus according to Embodiment 1;

FIG. 5 is a block diagram representing the configuration of an electronic control apparatus according to Embodiment 2;

FIG. 6 is a flowchart representing an example of signal-allocation changing processing by a signal processing means in the electronic control apparatus according to Embodiment 2;

FIG. 7 is a timing chart representing an example of signal-allocation changing processing by the signal processing means in the electronic control apparatus according to Embodiment 2;

FIG. 8 is a flowchart representing an example of signal allocation processing by a signal processing means in an electronic control apparatus according to Embodiment 3;

FIG. 9 is a timing chart representing an example of signal-allocation changing processing by the signal processing means in the electronic control apparatus according to Embodiment 3;

FIG. 10 is a flowchart representing examples of signal-allocation changing processing and error-status-signal output processing by the signal processing means in the electronic control apparatus according to Embodiment 3;

FIG. 11 is a timing chart representing an example of signal allocation processing by the signal processing means in a transient period in which a power source starts, in the electronic control apparatus according to Embodiment 3; and

FIG. 12 is a block diagram representing an example of the hardware configuration of each of the signal processing means and a control calculation processing means in the electronic control apparatus according to each of Embodiments 1 through 3.

### MODE FOR CARRYING OUT THE INVENTION

### Embodiment 1

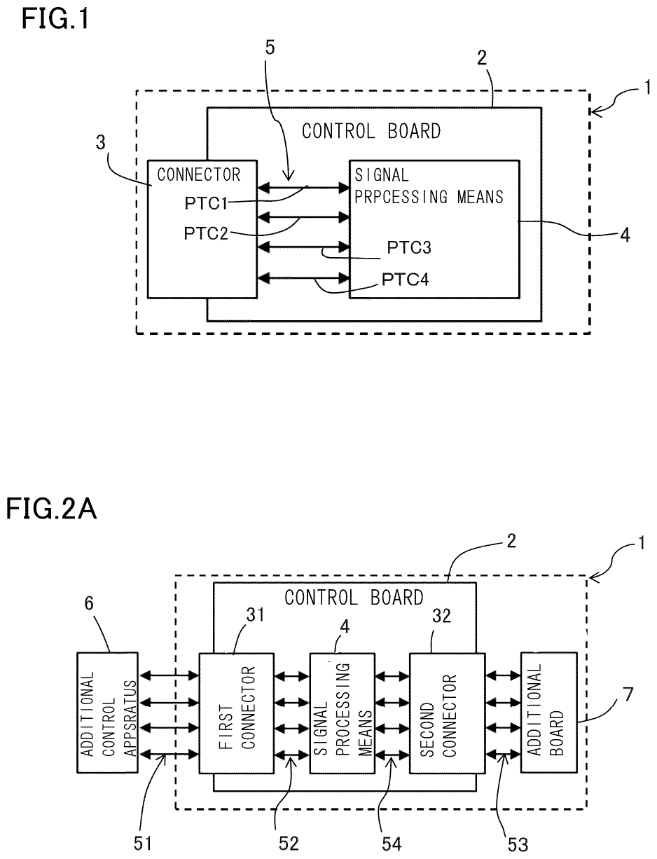

FIG. 1 is a block diagram representing the configuration of an electronic control apparatus according to Embodiment 1. In FIG. 1, the electronic control apparatus 1 has a control board 2, a connector 3, and a signal processing means 4. The connector 3 and the signal processing means 4 are electronic components mounted on the control board 2; they are electrically connected with each other by way of a signal wiring lead 5 provided on the control board 2 through printing, for example. In the represented example, the signal wiring lead 5 includes four individual signal wiring leads PTC1, PTC2, PTC3, and PTC4. In addition, each of the individual signal wiring leads PTC1, PTC2, PTC3, and PTC4 is not limited to a single lead but may collectively include two or more wiring leads, such as differential-signal wiring leads and parallel signal wiring leads.

The connector 3 has a function of transferring input/output signals between the signal processing means 4 and an external apparatus outside the electronic control apparatus 1 and a function of transferring input/output signals between the signal processing means 4 and other boards or components inside the electronic control apparatus 1; the connector 3 is provided with two or more connector pins. In addition, in FIG. 1, the external apparatuses, the inner other boards, or the inner components to be connected with the connector 3 are omitted.

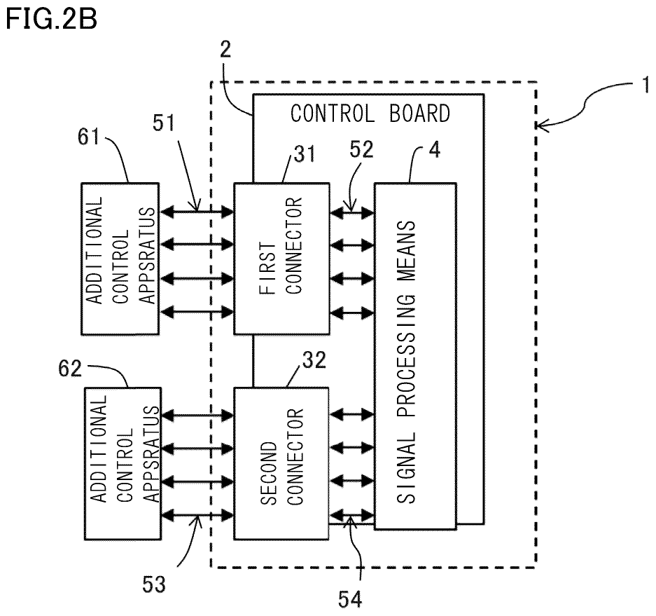

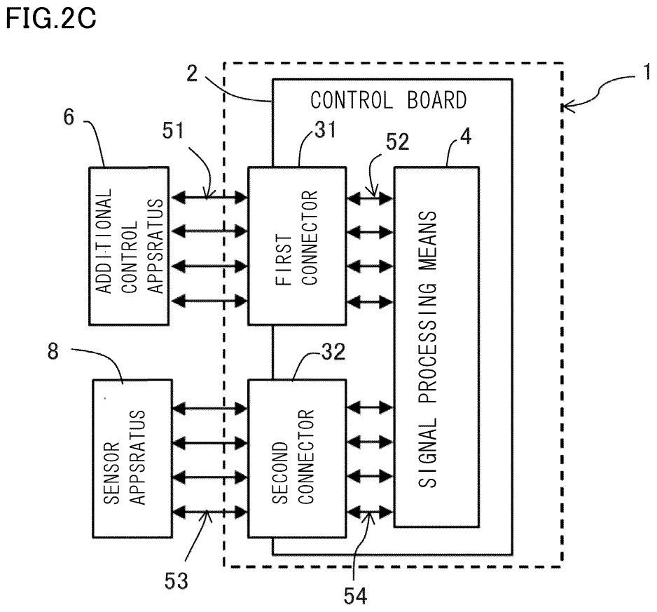

It may be allowed that two or more connectors 3 are mounted on the control board 2. FIG. 2A is a block diagram representing the configuration of a first variant example in the electronic control apparatus according to Embodiment 1; FIG. 2A represents the case where two connectors are provided. As represented in FIG. 2A, a first connector 31 and a second connector 32 are mounted on the control board 2.

The first connector 31 is electrically connected with an additional control apparatus 6 existing outside the electronic control apparatus 1, by way of two or more signal wiring lead 51. The first connector 31 and the signal processing means are electrically connected with each other by way of a signal wiring lead 52 provided on the control board 2 through printing, for example. The first connector 31 is utilized for transferring signals between the additional control apparatus 6 and the signal processing means 4.

The second connector 32 is electrically connected with an additional board 7 provided inside the electronic control apparatus 1, by way of two or more signal wiring leads 53. The first connector 32 and the signal processing means 4 are electrically connected with each other by way of a signal wiring lead 54 provided on the control board 2 through printing, for example. The second connector 32 is utilized for transferring signals between the additional board 7 and the signal processing means 4. Each of the signal wiring leads 51, 52, 53, and 54 includes two or more individual signal wiring leads.

FIG. 2B is a block diagram representing the configuration of a second variant example in the electronic control apparatus according to Embodiment 1; FIG. 2B represents the case where two connectors are provided. As represented in FIG. 2B, the first connector 31 and the second connector 32 are mounted on the control board 2.

The first connector 31 is electrically connected with a first additional control apparatus 61 existing outside the electronic control apparatus 1, by way of the signal wiring lead 51. The first connector 31 and the signal processing means 4 are electrically connected with each other by way of the signal wiring lead 52 provided on the control board 2 through printing, for example. The first connector 31 is utilized for transferring signals between the first additional control apparatus 61 and the signal processing means 4.

The second connector 32 is electrically connected with a second additional control apparatus 62 provided outside the electronic control apparatus 1, by way of the signal wiring lead 53. The first connector 32 and the signal processing means 4 are electrically connected with each other by way of the signal wiring lead 54 provided on the control board 2 through printing, for example. The second connector 32 is utilized for transferring signals between the second additional control apparatus 62 and the signal processing means 4. Each of the signal wiring leads 51, 52, 53, and 54 includes two or more individual signal wiring leads.

FIG. 2C is a block diagram representing the configuration of a third variant example in the electronic control apparatus according to Embodiment 1; FIG. 2C represents the case where two connectors are provided. As represented in FIG. 2C, the first connector 31 and the second connector 32 are mounted on the control board 2.

The first connector 31 is electrically connected with the additional apparatus 6 existing outside the electronic control apparatus 1, by way of the signal wiring lead 51. The first connector 31 and the signal processing means 4 are electrically connected with each other by way of the signal wiring lead 52 provided on the control board 2 through printing, for example. The first connector 31 is utilized for transferring signals between the additional control apparatus 6 and the signal processing means 4.

The second connector 32 is electrically connected with a sensor apparatus 8 provided outside the electronic control apparatus 1, by way of the signal wiring lead 53. The second connector 32 and the signal processing means 4 are electrically connected with each other by way of the signal wiring lead 54 provided on the control board 2 through printing, for example. The second connector 32 is utilized for transferring signals between the sensor apparatus 8 and the signal processing means 4. Each of the signal wiring leads 51, 52, 53, and 54 includes two or more individual signal wiring leads.

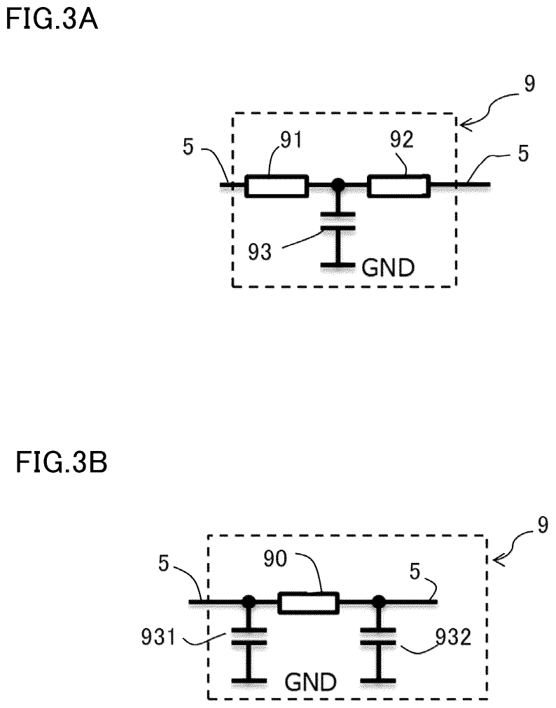

In foregoing FIG. 1, an exogenous-noise protection circuit is provided in the signal wiring lead 5 between the connector 3 and the signal processing means 4. The exogenous-noise protection circuit has a circuit configuration represented, for example, in FIG. 3A or FIG. 3B.

That is to say, FIG. 3A is a circuit diagram representing an example of an exogenous-noise protection circuit in the electronic control apparatus according to Embodiment 1. In FIG. 3A, an exogenous-noise protection circuit 9 is a T-type filter including a first resistor 91, a second resistor 92, and a capacitor 93. In addition, the exogenous-noise protection circuit 9 may be a three-terminal capacitor having the same noise-removal function.

FIG. 3B is a circuit diagram representing another example of the exogenous-noise protection circuit in the electronic control apparatus according to Embodiment 1. In FIG. 3B, then exogenous-noise protection circuit 9 is a n-type filter including a resistor 90, a first capacitor 931, and a second capacitor 932.

As represented in FIGS. 3A and 3B, the filter circuit, as the exogenous-noise protection circuit 9 having at least one capacitor, is a bilaterally symmetric T-type filter or n-type filter, can be applied to the signal wiring lead 5 in FIG. 1, regardless of the types of input/output signals flowing in the signal wiring lead 5, and can readily realize standardization of circuits and change in signal-allocation of the signal wiring leads 5. More specifically, the exogenous-noise protection circuit is provided in each of two or more individual signal wiring leads PTC1, PTC2, PTC3, and PTC4 included in the signal wiring lead 5.

In addition, the filter circuit, as the exogenous-noise protection circuit represented in FIGS. 3A and 3B, is provided also in the signal wiring leads 51, 52, 53, and 54 in foregoing FIGS. 2B and 2C, and can readily realize standardization of circuits and change in signal-allocation of each of the signal wiring leads 51, 52, 53, and 54.

Next, the operation by the electronic control apparatus according to Embodiment 1 represented in FIG. 1 will be explained. The signal processing means 4 has a signal-allocation function of allocating input/output signals of the connector 3 to the individual signal wiring leads PTC1, PTC2, PTC3, and PTC4 included in the signal wiring lead 5 connected with the connector 3 and a signal-allocation changing function of changing the signal allocation in accordance with the respective states of the input/output signals that have already been allocated to the individual signal wiring leads PTC1, PTC2, PTC3, and PTC4.

Specifically, the signal processing means 4 is configured with, for example, a PLD (Programmable Logic Device), an ASIC (Application Specific Integrated Circuit), a microcomputer (Micro Computer), an MCU (Micro Controller Unit), or the like; the signal processing means 4 in each of the variant examples represented in foregoing FIGS. 2A, 2B, and 2C has the same configuration.

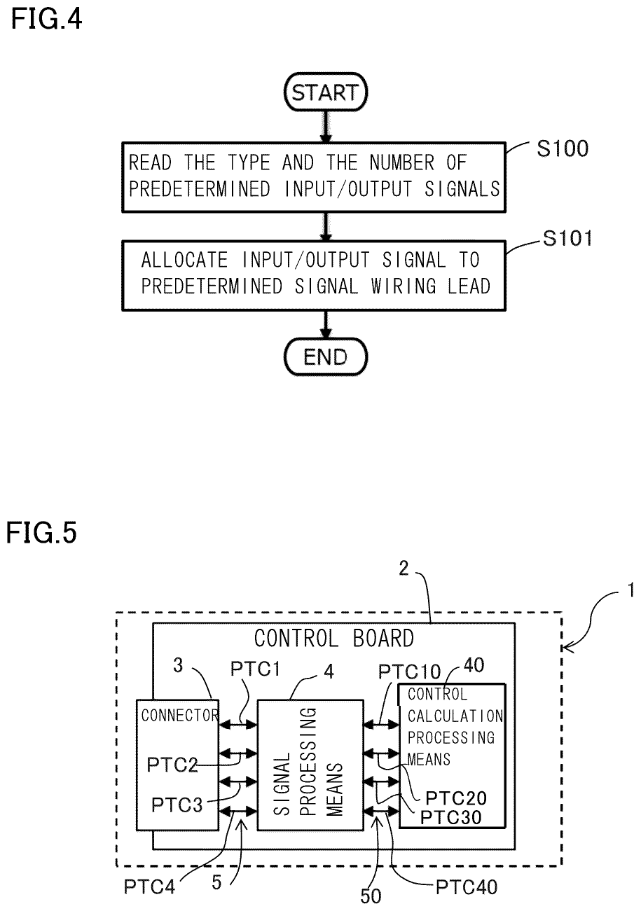

Next, there will be explained signal allocation processing, by the signal processing means 4, that is applied to the individual signal wiring leads PTC1, PTC2, PTC3, and PTC4 included in the signal wiring lead 5. FIG. 4 is a flowchart representing an example of signal allocation processing by the signal processing means in the electronic control apparatus according to Embodiment 1. In FIG. 4, in the step S100, the signal processing means 4 reads predetermined types of input/output signals and the number thereof. For example, the types of input/output signals and the number thereof are read from storage media provided inside and outside a PLD, an ASIC, a microcomputer, an MCU, or the like, as the signal processing means 4.

In the step S101, the signal processing means 4 allocates the input/output signals to the individual signal wiring leads PTC1, PTC2, PTC3, and PTC4 and then ends the processing.

The restriction (the upper limit) such as the number of allocations in the allocation of the input/output signals to the individual signal wiring leads PTC1, PTC2, PTC3, and PTC4 is read, for example, from storage media provided inside or outside or inside and outside a PLD, an ASIC, or the like included in the signal processing means 4. In addition, recording of the types and the number of the input/output signals in the storage media is performed in a product-manufacturing process; different specifications are determined depending on customers and models.

The signal processing means 4 is configured in such a way as to be able to change signal allocation to the individual signal wiring leads PTC1, PTC2, PTC3, and PTC4 in accordance with the operation state of the electronic control apparatus 1 after allocating, as described above, the predetermined input/output signals to the individual signal wiring leads PTC1, PTC2, PTC3, and PTC4 included in the connector 3.

For example, the specification and the priority degree of a signal, such as an error-status signal, notifying of an operational abnormality are preliminarily read from the foregoing storage media; then, when an abnormality occurs in the electronic control apparatus 1, the allocation of a signal to any one of the individual signal wiring leads PTC1, PTC2, PTC3, and PTC4 can be changed to the allocation of an error signal whose priority degree is higher than that of each of the input/output signals. In addition, this matter also applies to each of the variant examples represented in FIGS. 2A, 2B, and 2C.

As described above, the electronic control apparatus according to Embodiment 1 has a control board, a connector mounted on the control board, and a signal processing means mounted on the control board, and can arbitrarily set signal allocation to be applied to signal wiring leads between the connector and the signal processing means, in accordance with, for example, the type of an automobile, an apparatus to be controlled, or the like. Moreover, it is made possible that even when boards and components, including connectors and being mounted, are standardized, signal allocation is freely set without changing signal wiring leads; thus, compatibility between diversity and universality, shortening of the development period, cost reduction, and the like become possible.

Furthermore, because being a symmetric filter circuit including at least one capacitor, the exogenous-noise protection circuit provided in each of the signal wiring leads between the connector and the signal processing means can be applied to each of the signal wiring leads regardless of the kind of an input/output signal; thus, standardization of circuits and change in signal allocation by the signal processing means can readily be realized.

Still moreover, because being configured in such a way as to be able to change the allocation of the input/output signals to the respective signal wiring leads to the allocation of signals whose priority degrees are higher than those of the input/output signals, the signal processing means can quickly respond, for example, to a change in the state of the electronic control apparatus; thus, the convenience and the soundness of the whole system including the electronic control apparatus and the outside thereof can be maintained.

### Embodiment 2

Next, an electronic control apparatus according to Embodiment 2 will be explained. The electronic control apparatus according to Embodiment 1 is configured in such a way as to set signal allocation to the signal wiring leads between the connector and the signal processing means and in such a way as to be able to change the signal allocation; the electronic control apparatus according to Embodiment 2 further includes a control calculation processing means mounted on the control board and is configured in such a way as to be able to change signal allocation to the signal wiring leads between the connector and the signal processing means or to the signal wiring leads between the control calculation processing means and the signal processing means, based on permission from the control calculation processing means.

FIG. 5 is a block diagram representing the configuration of the electronic control apparatus according to Embodiment 2. In FIG. 5, an electronic control apparatus 1 has a control board 2, a connector 3, a signal processing means 4, and a control calculation processing means 40. As is the case with each of the variant examples represented in FIGS. 2A, 2B, and 2C for the electronic control apparatus according to foregoing Embodiment 1, two or more connectors 3 may be mounted on the control board 2.

Each of the signal processing means 4 and the control calculation processing means 40 is an electronic component mounted on the control board 2. The signal processing means 4 and the control calculation processing means 40 are electrically connected with each other by way of a signal wiring lead 50 provided on the control board 2 through printing, for example. The signal wiring lead 50 includes two or more individual signal wiring leads.

In addition, the control calculation processing means 40 has a function of performing predetermined calculation processing in accordance with input/output signals and outputting the result of the calculation processing, as an output signal, to the signal wiring lead 50. Specifically, the control calculation processing means 40 is configured with, for example, a PLD, an ASIC, a microcomputer, an MCU), or the like.

Each of the connector 3 and the signal processing means 4 is an electronic component mounted on the control board 2; they are electrically connected with each other by way of the signal wiring lead 5 provided on the control board 2 through printing, for example. As is the case with Embodiment 1, the signal wiring lead 5 includes two or more individual signal wiring leads. As is the case with Embodiment 1, the connector 3 has a function of transferring signals between the signal processing means 4 and an external apparatus outside the electronic control apparatus 1 and a function of transferring signals between the signal processing means 4 and other boards or components inside the electronic control apparatus 1.

The individual signal wiring leads PTC1, PTC2, PTC3, and PTC4 included in the signal wiring lead 5 between the connector 3 and the signal processing means 4 correspond to the individual signal wiring leads PTC10, PTC20, PTC30, and PTC40 included in the signal wiring lead 50 between the control calculation processing means 40 and the signal processing means 4; the same respective signals are allocated to the individual signal wiring leads PTC1 and PTC10, to the individual signal wiring leads PTC2 and PTC20, to the individual signal wiring leads PTC3 and PTC30, and to the individual signal wiring leads PTC4 and PTC40. In addition, an exogenous-noise protection circuit is provided in each of the individual signal wiring leads PTC1, PTC2, PTC3, and PTC4 between the connector 3 and the signal processing means 4. The exogenous-noise protection circuit has a circuit configuration represented, for example, in foregoing FIG. 3A or FIG. 3B. In addition, each of the individual signal wiring leads PTC1, PTC2, PTC3, and PTC4 and each of the individual signal wiring leads PTC10, PTC20, PTC30, and PTC40 are not limited to a single lead but may collectively include two or more wiring leads, such as differential-signal wiring leads and parallel signal wiring leads.

The signal processing means 4 has a function of allocating respective predetermined input/output signals to the individual signal wiring leads PTC1, PTC2, PTC3, and PTC4 included in the signal wiring lead 5 between the connector 3 and the signal processing means 4 and the individual signal wiring leads PTC10, PTC20, PTC30, and PTC40 included in the signal wiring lead 50 between the control calculation processing means 40 and the signal processing means 4. The signal allocation processing by the signal processing means 4 to the signal wiring leads 5 and 50 is performed in a manner the same as that of the flowchart represented in FIG. 4 for the electronic control apparatus according to foregoing Embodiment 1.

In addition, when in a transient period in which the power source of the electronic control apparatus 1 is activated, the signal processing means 4 is started after the control calculation processing means 40 starts, the signal processing means 4 can perform the signal allocation, while considering the types of predetermined input/output signals, the number thereof, and the like, by use of the storage media provided in the control calculation processing means 40; thus, security measures can be realized along with reduction of the number of the components.

Moreover, as described later, the electronic control apparatus according to Embodiment 2 makes it possible that even when, for the sake of compatibility between diversity and universality, which is the issue of an electronic control apparatus, shortening of the development period, and cost reduction, control boards and components, including connectors, to be mounted are standardized, the signal allocation can freely be changed without changing the arrangement of the signal wiring leads and the like.

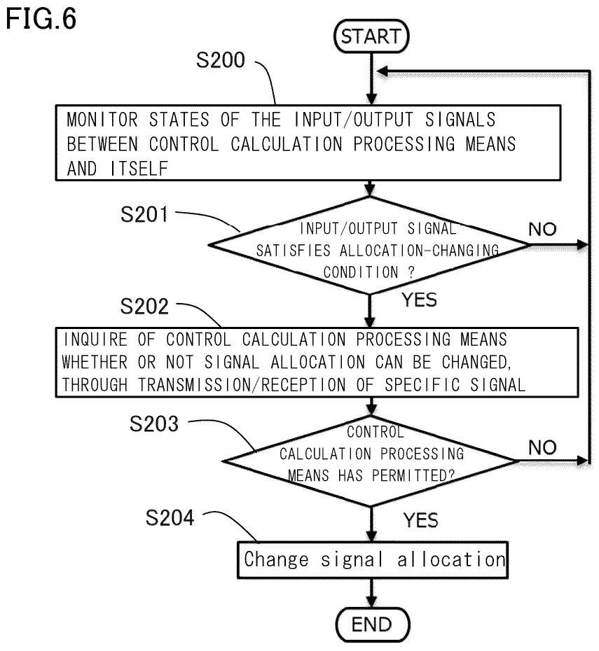

The signal processing means 4 has a signal-allocation changing function of changing signal allocation to the individual signal wiring leads PTC10, PTC20, PTC30, and PTC40 included in the signal wiring lead 50, in collaboration with the control calculation processing means 40 and in accordance with the states of the input/output signals. FIG. 6 is a flowchart representing an example of signal-allocation changing processing by the signal processing means in the electronic control apparatus according to Embodiment 2.

In FIG. 6, in the step S200, the signal processing means 4 monitors the states of the input/output signals between the control calculation processing means 40 and itself. More specifically, for example, the signal processing means 4 ascertains whether or not any one of the input/output signals is fixed due to wire breaking of the corresponding one of the individual signal wiring leads PTC10, PTC20, PTC30, and PTC40 included in the signal wiring lead 5. In the case where in the step S200, an abnormality in the input/output signals is detected, the step S200 is followed by the step S201.

In the step S201, the signal processing means 4 considers the priority degree preliminarily defined for the input/output signal in which an abnormality has been detected; in the case where, in terms of realizing the function of the electronic control apparatus 1, the input/output signal in which the abnormality has been detected is a signal having a priority degree higher than that of each of the other input/output signals, the signal processing means 4 considers changing the signal allocation where another input/output signal having a priority degree lower than that of the input/output signal in which the abnormality has been detected is allocated to the individual signal wiring lead to the signal allocation where the input/output signal in which the abnormality has been detected and has a higher priority degree is allocated to the foregoing individual signal wiring lead. That is to say, the signal processing means 4 determines whether or not the input/output signal satisfies a signal-allocation changing condition.

In the case where in the step S201, it is determined that the priority degree of the input/output signal in which the abnormality has been detected is higher than that of each of the other input/output signals, it is determined that the signal-allocation changing condition is satisfied (YES) ; then, the step S201 is followed by the step S202. In contrast, in the case where the priority degree of the input/output signal in which the abnormality has been detected is lower than that of each of the other input/output signals, it is determined that the signal-allocation changing condition is not satisfied (NO); then, the step S200 is resumed and the processing in and after the step S200 is repeated.

In the step S202, the signal processing means 4 transmits the input/output signal in which the abnormality has been detected and the change in the signal allocation to the control calculation processing means 40, through transmission and reception of a specific signal in serial communication or the like, so as to inquire whether or not the signal allocation can be changed.

Next, in the step S203, it is determined whether or not permission for the change in the signal allocation has been obtained; in the case where the permission for the change in the signal allocation has been obtained (YES), the step S203 is followed by the step S204, where the signal allocation is changed; then, the processing is ended. In contrast, in the case where it is determined in the step S203 that the permission for the change in the signal allocation has not been obtained (NO), the step S200 is resumed and the processing in and after the step S200 is repeated.

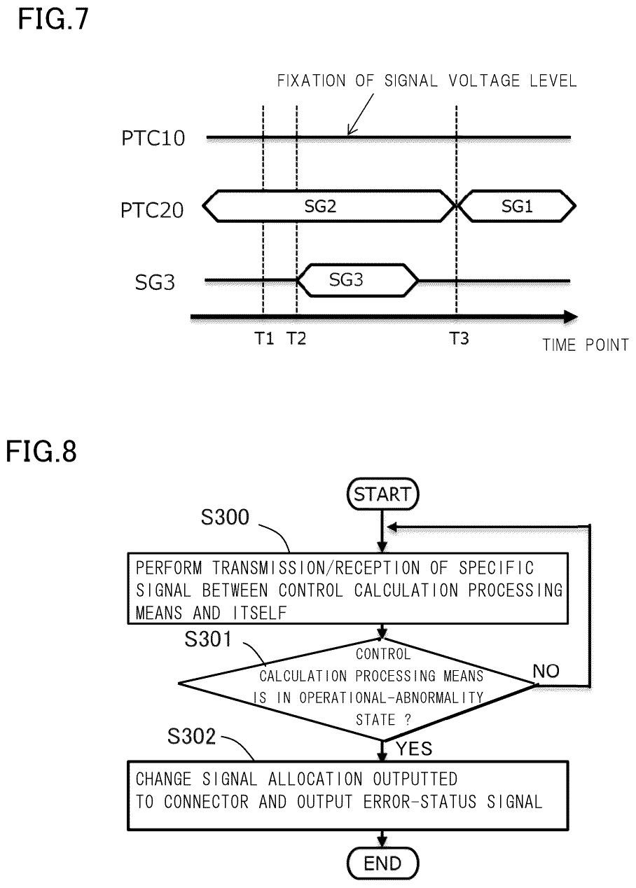

FIG. 7 is a timing chart representing an example of signal-allocation change by the signal processing means in the electronic control apparatus according to Embodiment 2; the ordinate denotes the individual signal wiring leads PTC10 and PTC20 and a specific signal SG3 in a specific communication such as serial communication between the signal processing means 4 and the control calculation processing means 40; the abscissa denotes time points.

FIG. 7 represents the case where the individual signal wiring lead PTC10 fails, for example, due to wire breaking or the like and then the signal voltage level of an input/output signal SG1 allocated to the individual signal wiring lead PTC10 is fixed to “0”. An input/output signal SG2 is allocated to the individual signal wiring lead PTC20. In addition, it is assumed that the priority degree of the input/output signal SG1 is higher than that of the input/output signal SG2.

Let's assume that at a time point T1, the signal processing means 4 detects that the voltage level of the input/output signal SG1 allocated to the individual signal wiring lead PTC10 is fixed to “0”. The fixation of the voltage level of the input/output signal SG1 can be detected, for example, in the case where the voltage level does not change during a predetermined specific time, or from a comparison with a voltage-level change of another input/output signal.

Next, at a time point T2, by use of the specific signal SG3 in a specific communication such as serial communication with the control calculation processing means 40, the signal processing means 4 inquires of the control calculation processing means 40 whether or not the signal allocation can be changed. In response to this inquiry, the control calculation processing means 40 notifies the signal processing means 4 of the permission for changing the signal allocation to the individual signal wiring lead PTC20 by use of the specific signal SG3, because the priority degree of the input/output signal SG1 is higher than that of the input/output signal SG2 allocated to the sound individual signal wiring lead PTC20.

At a time point T3, the signal processing means 4 that has obtained the permission for the signal allocation change from the control calculation processing means 40 performs a signal allocation change in which the input/output signal SG1 in place of the input/output signal SG2 is allocated to the individual signal wiring lead PTC20. As described above, the individual signal wiring leads PTC10, PTC20, PTC30, and PTC40 included in the signal wiring lead 50 correspond to the individual signal wiring leads PTC1, PTC2, PTC3, and PTC4 included in the signal wiring lead 5. In addition, because at the time point T3, the signal processing means 4 does not change the signal allocation to the individual signal wiring leads PTC1 and PTC2 included in the signal wiring lead 5 between the connector 3 and the signal processing means 4, the input/output signal SG1 is continuously transferred through the individual signal wiring lead PTC1 and the transfer of the input/output signal SG2 whose priority degree is low is cancelled.

As described above, the electronic control apparatus according to Embodiment 2 has the connector 3, the signal processing means 4, and the control calculation processing means 40 on the control board 2 and can arbitrarily change the signal allocation to the signal wiring lead 5 between the connector and the signal processing means, in collaboration of the signal processing means 4 and the control calculation processing means 40; thus, it is made possible that even when control boards and components including connectors and being mounted thereon, are standardized, signal allocation to the signal wiring lead is freely changed without changing the signal wiring leads; therefore, compatibility between diversity and universality, shortening of the development period for the apparatus, cost reduction, and the like can be realized.

Moreover, when in a transient period in which the power source of the electronic control apparatus 1 is activated, the signal processing means 4 is started after the control calculation processing means 40 starts, the signal processing means 4 can perform the signal allocation, while considering the types of input/output signals, the number thereof, and the like stored by use of the storage media provided in the control calculation processing means 40; thus, security measures can be realized along with reduction of the number of the components.

In addition, because based on the signal wiring lead 50 between the control calculation processing means 40 and itself, the signal processing means 4 is configured in such a way as to change signal allocation to a signal wiring lead, in accordance with the state of an input/output signal and in comparison with predetermined priority order, it is made possible that, for example, even when a signal abnormality occurs, the operation of the electronic control apparatus is continued by changing signal allocation to the signal wiring lead; thus, it is made possible that even when, for the sake of compatibility between diversity and universality, which is the issue of an electronic control apparatus, shortening of the product-development period, and cost reduction, boards and components including connectors and being mounted are standardized, signal allocation to a signal wiring lead is arbitrarily changed without changing the arrangement of the signal wiring leads.

### Embodiment 3

Next, an electronic control apparatus according to Embodiment 3 will be explained. The electronic control apparatus according to Embodiment 2 has the control calculation processing means on the control board and changes the signal allocation to the signal wiring lead between the connector and the signal processing means, in such a way as to change the signal allocation to the signal wiring lead between the control calculation processing means and the signal processing means in accordance with the state of an input/output signal; however, the electronic control apparatus according to Embodiment 3 changes input/output-signal allocation to the signal wiring lead between the signal processing means and the connector in accordance with the state of the control calculation processing means. The configuration of the electronic control apparatus according to Embodiment 3 is the same as that of the electronic control apparatus according to Embodiment 2.

In FIG. 5, the signal processing means 4 has a function of monitoring the state of the control calculation processing means 40. The monitoring of the control calculation processing means 40 by the signal processing means 4 is performed based on a specific signal transmitted and received between the signal processing means 4 and the control calculation processing means 40 through the signal wiring lead 50 between the signal processing means 4 and the control calculation processing means 40. As the specific signal, for example, a watchdog timer signal, an inquiry signal and a response signal in serial communication, or the like is/are utilized.

In addition, the signal processing means 4 has a function of changing signal allocation to the signal wiring lead 5 between the signal processing means 4 and the connector 3, in accordance with the state of the control calculation processing means 40. FIG. 8 is a flowchart representing an example of signal allocation processing by the signal processing means in the electronic control apparatus according to Embodiment 3. In FIG. 8, in the step S300, the signal processing means 4 performs transmission and reception of a specific signal between the control calculation processing means 40 and itself, through the signal wiring lead 50 between the control calculation processing means 40 and itself. As described above, as the specific signal, for example, a watchdog timer signal, an inquiry signal and a response signal in serial communication, or the like is/are utilized.

Next, in the step S301, based on the result of the specific-signal transmission and reception between the control calculation processing means 40 and itself, the signal processing means ascertains the operation state of the control calculation processing means 40; in the case where an operational abnormality in the control calculation processing means 40 is detected (YES), the step S301 is followed by the step S302; in the case where no operational abnormality in the control calculation processing means 40 is detected (NO), the step S300 is resumed and then the processing in and after the step S300 is repeated.

In the step S302, the signal processing means 4 changes signal allocation in such a way that in place of an input/output signal that has been allocated to at least one of the individual signal wiring leads PTC1, PTC2, PTC3, and PTC4 of the signal wiring lead 5 between the signal processing means 4 and the connector 3, an error-status signal is allocated thereto; then, the processing is ended.

As a way to specifically realize the signal-allocation change in the step S302, for example, it is conceivable that an error-status signal is outputted to at least one of the individual signal wiring leads PTC1, PTC2, PTC3, and PTC4 in the signal wiring lead 5, through LIN (Local Interconnect Network) communication, CAN (Controller Area Network) communication, or the like. In addition, each of the individual signal wiring leads PTC1, PTC2, PTC3, and PTC4 is not limited to a single lead but may collectively include two or more wiring leads, such as differential-signal wiring leads and parallel signal wiring leads.

In particular, in the case of CAN communication, when the control calculation processing means 40 does not make any response, an inquiry signal from a higher-hierarchy controller outside the electronic control apparatus 1 impose a high load on the communication line (Bus) of the CAN communication; however, when in place of the control calculation processing means 40, the signal processing means 4 outputs the error-status signal early, not only the high load on the communication line of the CAN communication is suppressed, but also the higher-hierarchy controller can hasten fail-safe action; thus, the soundness of the whole system can be raised.

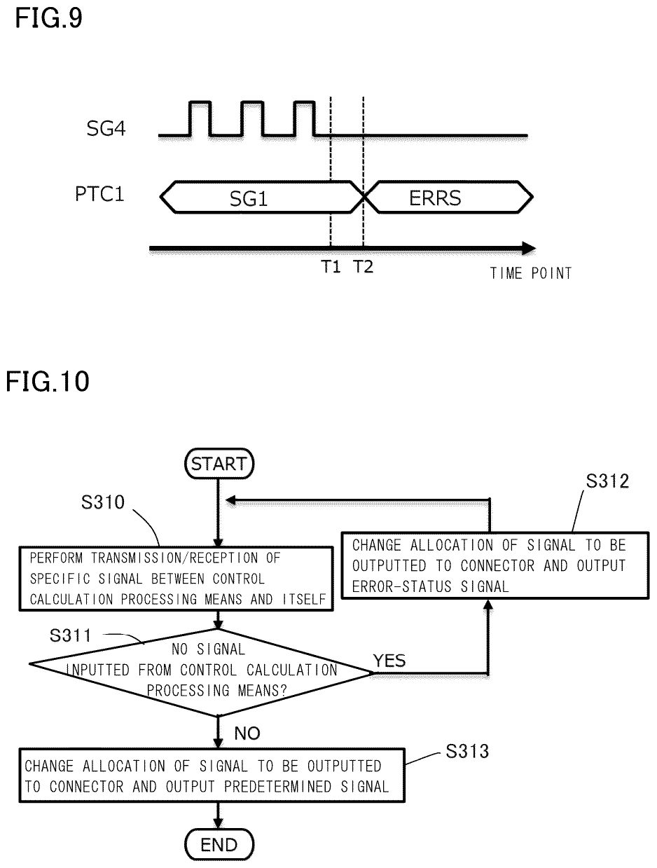

FIG. 9 is a timing chart representing an example of signal-allocation changing processing by the signal processing means in the electronic control apparatus according to Embodiment 3; the ordinate denotes a specific signal SG4 in specific communication between the signal processing means 4 and the connector 3 and the individual signal wiring lead PTC1 included in the signal wiring lead 5; the abscissa denotes time points.

In FIG. 9, the control calculation processing means 40 outputs a watchdog timer signal for the specific signal SG4 included in the signal wiring lead 50 between the signal processing means 4 and itself ; the signal processing means 4 detects an operational abnormality in the control calculation processing means 40, by monitoring the specific signal SG4 including the foregoing watchdog timer signal.

When detecting an operational abnormality in the control calculation processing means 40, the signal processing means 4 changes the signal allocation to the individual signal wiring lead PTC1, which is one of the individual signal wiring leads included in the signal wiring lead 5 between the connector 3 and itself. In other words, the signal processing means 4 changes the signal allocation to the individual signal wiring lead PTC1, in such a way that in place of the input/output signal SG1 that has been allocated to the individual signal wiring lead PTC1, an error-status signal ERRS indicating an operational abnormality in the control calculation processing means is allocated thereto.

More specifically, at a time point Tl represented in FIG. 9, an operational abnormality in the control calculation processing means 40 occurs; then, the signal processing means 4 determines that the voltage level of the specific signal SG4 including the watchdog timer signal has been fixed to “0”. Next, at a time point T2, the signal processing means 4 changes the signal, to be allocated to the individual signal wiring lead PTC1 included in the signal wiring lead 5 between the connector 3 and itself, from the input/output signal SG1 to the error-status signal ERRS indicating the operational abnormality in the control calculation processing means, and then notifies other apparatuses outside the electronic control apparatus 1 of the abnormality in the electronic control apparatus 1.

In addition, when in a transient period in which the power source of the electronic control apparatus 1 is activated, the signal processing means 4 is started before the control calculation processing means 40 starts, the signal processing means 4 can perform the signal allocation to the signal wiring lead 5 between the connector 3 and itself, during the time before the control calculation processing means 40 starts, in the case where the control calculation processing means 40 inputs no specific signals, and can output the error-status signal ERRS indicating operation-state information such as the fact that the electronic control apparatus 1 is in a power-source starting sequence or on standby.

In particular, the control calculation processing means 40 corresponding to functional soundness has a long self-diagnosis time at a time of starting and shortening of the starting time is difficult; therefore, when in place of the control calculation processing means 40, the signal processing means 4 outputs the error-status signal ERRS early, the starting time of the whole system including the higher-hierarchy controller can be shortened.

FIG. 10 is a flowchart representing examples of signal-allocation changing processing and error-status-signal output processing by the signal processing means in the electronic control apparatus according to Embodiment 3. The flowchart in FIG. 10 represents an example of signal-changing processing in which when in a transient period in which the power source of the electronic control apparatus 1 is activated, the signal processing means 4 is started before the control calculation processing means 40 starts and in the case where during the time before the control calculation processing means 40 starts, the control calculation processing means 40 inputs no specific signal SG4 to the signal processing means 4, the signal processing means 4 changes the signal, to be allocated to the signal wiring lead 5 between the connector 3 and itself, from the input/output signal SG1 to the error-status signal ERRS.

That is to say, in the step S310 in FIG. 10, the signal processing means 4 performs transmission and reception of the specific signal SG4 between the control calculation processing means 40 and itself; then, the step S310 is followed by the step S311. In the step S311, the signal processing means 4 determines whether or not there exists input of the specific signal SG4 from the control calculation processing means 40.

In the case where it is determined in the step S311 that there exists no input of the specific signal SG4 (YES), the step S311 is followed by the step S312, where the signal processing means 4 changes the signal allocation to the signal wiring lead 5 between the connector 3 and itself so as to output the error-status signal ERRS instead of the previous input/output signal SG1; then, the step S310 is resumed, and the processing in and after the step S310 is repeated.

In contrast, in the case where it is determined in the step S311 that there exists input of the specific signal SG4 (NO), the step S311 is followed by the step S313, where the signal processing means 4 changes the signal allocation to the signal wiring lead 5 between the connector 3 and itself so as to output a predetermined communication signal SXS instead of the previous error-status signal ERRS; then, the processing is ended.

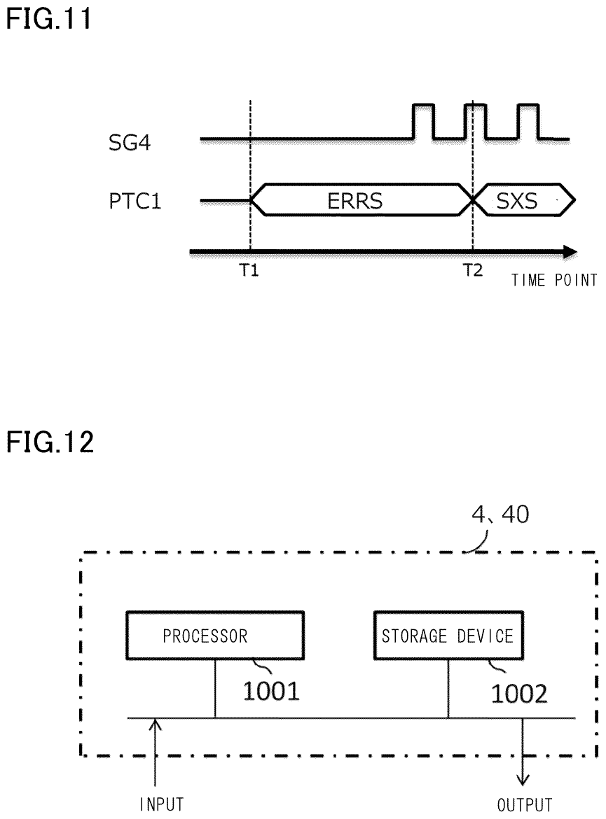

FIG. 11 is a timing chart representing an example of signal allocation processing by the signal processing means in a transient period in which the power source starts, in the electronic control apparatus according to Embodiment 3. FIG. 11 represents the case where the signal processing means 4 changes the signal allocation to the individual signal wiring lead PTC1 included in the signal wiring lead 5 between the connector 3 and itself. In addition, FIG. 11 represents the case where the signal processing means 4 monitors a watchdog timer signal to be inputted to the specific signal SG3 transmitted and received between the control calculation processing means 40 and itself, and then determines whether or not the control calculation processing means 40 has been activated.

At a time T1 represented in FIG. 11, the signal processing means 4 is activated before the control calculation processing means 40, ascertains that no watchdog timer signal is inputted to the specific signal SG3, changes the signal, to be allocated to the individual signal wiring lead PTC1, from the original input/output signal to the error-status signal ERRS, and then outputs the error-status signal ERRS.

Next, at a time point T2, the signal processing means 4 ascertains s t that a watchdog timer signal having a predetermined pattern has been inputted to the specific signal SG3, and then changes the signal, to be allocated to the individual signal wiring lead PTC1, from the error-status signal ERRS to the predetermined communication signal SXS. Because receiving the communication signal SXS, the other control apparatuses soundly operate thereafter.

As described above, the electronic control apparatus according to Embodiment 3 has a control board and a connector, a signal processing means, and a control calculation processing means mounted on the control board, and can arbitrarily change signal allocation to be applied to signal wiring leads between the connector and the signal processing means; thus, it is made possible that even when boards and components including connectors and being mounted on the control board are standardized, signal allocation to the signal wiring leads is freely changed without changing the signal wiring leads; thus, compatibility between diversity and universality, shortening of the product-development period, and cost reduction become possible.

Moreover, the signal processing means 4 monitors the operation state of the control calculation processing means 40; in the case where an abnormality in the control calculation processing means 40 is detected, the signal processing means 4 changes the signal, to be allocated and outputted to the signal wiring lead 5 between the connector 3 and itself, to the error-status signal, so that in place of the control calculation processing means 40, the signal processing means 4 can notify the outside of the electronic control apparatus 1 of the abnormality; therefore, the whole vehicle system can hasten the fail-safe action and the soundness of the system can be raised.

Still moreover, the control calculation processing means 40 is provided, and in a transient period in which the power source of the electronic control apparatus 1 is activated, the signal processing means 4 is started before the control calculation processing means 40; thus, in the case where before the control calculation processing means 40 is activated, there exists no input of the specific signal from the control calculation processing means 40, the signal processing means 4 can change the signal allocation to the signal wiring lead 5 between the connector 3 and itself so as to output the error-status signal.

In particular, because the control calculation processing means 40 corresponding to functional soundness has a prolonged self-diagnosis time at a time of starting, shortening of the starting time is difficult; however, when in place of the control calculation processing means 40, the signal processing means 4 outputs the error-status signal early, the starting time of the whole system including the higher-hierarchy controller can be shortened.

FIG. 12 is a block diagram representing an example of the hardware configuration of each of the signal processing means and the control calculation processing means in the electronic control apparatus according to each of Embodiments 1 through 3. Each of the signal processing means 4 and the control calculation processing means 40 according to the present disclosure has a hardware configuration, for example, represented in FIG. 12. That is to say, in FIG. 12, each of the signal processing means 4 and the control calculation processing means 40 includes a processor 1001 and a storage device 1002. Although not illustrated, the storage device 1002 has a volatile storage device such as a random access memory and a nonvolatile auxiliary storage device such as a flash memory. Each of the signal processing means 4 and the control calculation processing means 40 executes a program inputted from the storage device 1002. In this case, the program is inputted from the auxiliary storage device to the processor 1001 by way of the volatile storage device. Moreover, the processor 1001 may output data such as a calculation result either to the volatile storage device of the storage device 1002 or to the auxiliary storage device by way of the volatile storage device. In addition, the signal processing means 4 and the control calculation processing means 40 may be integrated with each other or may be separated from each other.

The present application can be applied to an electronic control apparatus whose control subject is a vehicle driving system or to an electronic control apparatus for controlling the operation of an in-vehicle apparatus. In addition, the application of the electronic control apparatus according to the present disclosure is not limited to an in-vehicle apparatus.

Although the present application is described above in terms of various exemplary embodiments and implementations, it should be understood that the various features, aspects and functions described in one or more of the individual embodiments are not limited in their applicability to the particular embodiment with which they are described, but instead can be applied, alone or in various combinations to one or more of the embodiments. Therefore, an infinite number of unexemplified variant examples are conceivable within the range of the technology disclosed in the present application. For example, there are included the case where at least one constituent element is modified, added, or omitted and the case where at least one constituent element is extracted and then combined with constituent elements of other embodiments.

### DESCRIPTION OF REFERENCE NUMERALS

1: electronic control apparatus
2: control board
3: connector
31: first connector
32: second connector
4: signal processing means
40: control calculation processing means
5, 50, 51, 52, 53, 54: signal wiring lead
6, 61, 62: additional control apparatuses
7: additional board
8: sensor apparatus
9: exogenous-noise protection circuit
90: resistor
91: first resistor
92: second resistor
93: capacitor
931: first capacitor
932: second capacitor
PTC1, PTC2, PTC3, PTC4, PTC10, PTC20, PTC30, PTC40: individual signal wiring lead
SG1, SG2: input/output signal
SG3, SG4: specific signal
ERRS: error-status signal
SXS: communication signal

1.-14. (canceled)

15. An electronic control apparatus configured to control a control subject, comprising:
a control board;
a connector mounted on the control board; and
a signal processing means that is mounted on the control board and is electrically connected with the connector by way of a signal wiring lead provided on the control board,
wherein an input/output signal bound for the connector is applied to the signal wiring lead, and
wherein the signal processing means performs signal allocation in which the input/output signal is allocated to the signal wiring lead,
wherein the signal wiring lead has an exogenous-noise protection circuit, and
wherein the exogenous-noise protection circuit has at least one capacitor and has the same configuration, regardless of a type of the input/output signal.

16. The electronic control apparatus according to claim 15, wherein the signal processing means can change the signal allocation in such a way that among the input/output signals, an input/output signal whose priority degree is high is allocated to the signal wiring lead, in place of an input/output signal whose priority degree is low.

17. The electronic control apparatus according to claim 15, further comprising a control calculation processing means mounted on the control board, wherein the control calculation processing means is electrically connected with the signal processing means by way of a signal wiring lead other than the signal wiring lead provided on the control board.

18. The electronic control apparatus according to claim 17, wherein when obtaining permission for changing the signal allocation from the control calculation processing means, the signal processing means changes signal allocation to the signal wiring lead.

19. The electronic control apparatus according to claim 17, wherein the signal processing means changes signal allocation to the signal wiring lead in accordance with an abnormality state caused by breakage or shortcircuiting of the signal wiring lead.

20. The electronic control apparatus according to claim 17, wherein the signal processing means is activated after the control calculation processing means has been activated.

21. The electronic control apparatus according to claim 17, wherein the signal processing means is activated before the control calculation processing means is activated.

22. The electronic control apparatus according to claim 17, wherein the signal processing means monitors a state of the control calculation processing means by performing transmission and reception of a predetermined specific signal between the control calculation processing means and itself.

23. The electronic control apparatus according to claim 22, wherein when detecting operational abnormality in the control calculation processing means, the signal processing means outputs an error-status signal to the signal wiring lead electrically connecting the signal processing means with the connector.

24. The electronic control apparatus according to claim 22, wherein when not receiving the specific signal from the control calculation processing means, the signal processing means outputs an error-status signal to the signal wiring lead electrically connecting the signal processing means with the connector.

25. The electronic control apparatus according to claim 22, wherein the specific signal is a watchdog timer signal.

26. The electronic control apparatus according to claim 22, wherein the specific signal is transmitted and received through communication.

27. The electronic control apparatus according to claim 15, wherein the control subject is an in-vehicle apparatus mounted in a vehicle.
